(19) United States
(12) Patent Application Publication
(10) Pub. No.: US 2016/0156352 A1
(43) Pub. Date: Jun. 2, 2016

(54) MODULAR TOUCH SWITCH

(71) Applicant: SWITCHBEE LTD., NATANYA (IL)

(72) Inventor: Amichai ZIV, NATANYA (IL)

(21) Appl. No.: 14/442,424

(22) PCT Filed: Nov. 13, 2013
(86) PCT No.: PCT/IL2013/050936

§ 371 Date: May 13, 2015

Related U.S. Application Data
(60) Provisional application No. 61/726,589, filed on Nov. 15, 2012.

(51) Int. Cl. H03K 17/96

(52) U.S. Cl. CPC H03K 17/9622

(57) ABSTRACT

The present invention relates to a modular touch element system, the system comprises: a plurality of touch element circuitry units (TECUs) a covering panel to cover the plurality of TECUs and to enable activation of one or more of the TECUs. The TECU according to embodiment of the invention are electrically insulated and may be used with any desired covering panel providing a completely modular and easily installed unit enjoying the advantages of touch sensitive switches.

### RELATED APPLICATION

The present invention gains priority from U.S. Provisional Patent Application Ser. No. 61/726589 filed on Nov. 15, 2012.

### FIELD OF THE INVENTION

The present invention relates to the field of touch operated electrical units such as touch switches.

### BACKGROUND OF THE INVENTION

Touch sensitive switches for operating electrical appliances, as opposed to mechanical switches used to make or break a mechanical connection, may use different properties of the human body. The most common touch sense method is capacitance sensing (by detecting the change in capacity due to the touch of a human finger). Other methods may include resistance touch panel, temperature (typically by use of buttons that are sensitive to the temperature of the human finger), radio reception (by detecting a change in radio-wave reception that occurs when the switch is touched by a human finger), and more.

Some touch sensitive switches are marketed as a single unit complete with a decorative glass/chrome panel. These switches, which usually have a smooth stylish panel, are promoted as elegant “retrofit” fixtures that can be connected to existing wires and which improve the esthetic standards of a room in which they are installed.

Indeed touch sensitive switches have several advantages, such as the fact that they do not easily accumulate dirt and moisture, can be easily cleaned and can provide chic to a room.

However, the touch sensitive units available today, being a complete non-modular unit, are designed for certain niches, the design of the whole product—electronics, PCB, and housing are designed especially for certain niche and cannot be installed in a differently sized or shaped niche.

Furthermore, each specific unit must pass all the regulation and standard requirements separately.

### SUMMARY OF THE INVENTION

Embodiments of the present invention provide a touch sensitive module that can be easily installed in any existing electrical box or niche. Touch element circuitry units (TECUs) according to embodiment of the invention are electrically insulated and may be used (optionally by using a simple adaptive frame) with any desired covering panel providing a completely modular and easily installed unit enjoying the advantages of touch sensitive switches.

The use of a module according to embodiments of the invention offers the liberty to use any desired covering panel and enables using a single covering panel to cover a plurality of modules, essentially providing multiple switches under a single covering panel.

The module according to embodiments of the invention can also be inserted to a variety of connection boxes whether it's rectangular or round (e.g., European connection box) by using a simple adaptive frame made of plastic, for instance.

Thus, embodiments of the invention offer the user greater flexibility in choosing the design of the panel they want to decorate their homes with and enable to use a single panel, which is smoother and cheaper to manufacture than having to use multiple panels for multiple switches.

Additionally, fulfilling regulation and standard requirements becomes much simpler by using a single module according to embodiments of the invention, that can fit any niche.

According to an aspect of some embodiments of the present invention there is provided a modular touch element system comprising a plurality of touch element circuitry units (TECUs) and at least one covering panel to cover the plurality of TECUs, the panel configured to enable activation of one or more of the TECUs.

In an embodiment each TECU is configured to be activated by touch, by pressure, by temperature change, humidity change or a combination thereof.

In an embodiment, the TECU comprises a capacitive sensitive area.

According to an embodiment the TECU comprises an elastomeric contacting element to connect between the capacitive sensitive area and the circuitry of a TECU.

According to an embodiment the system may include a conducting element positioned in between the capacitive sensitive area of the TECU and the covering panel, said conductive element being larger than the capacitive sensitive area.

According to another embodiment the conducting element is integrated within the covering panel.

According to another embodiment the conductive element is a conductive sheet attached on to or printed on a surface of the covering panel, said surface facing the circuitry of the TECU.

According to another embodiment the TECU comprises a coupling layer, the coupling layer positioned between the capacitive sensitive area and the covering panel.

According to another embodiment the system may include a capacitor and/or a resistor and/or dielectric material positioned in between the circuitry of the TECU and the capacitive sensitive area.

According to another embodiment the system may include a programmable component.

According to further another embodiment the programmable component determines the functional destiny of the TECU.

According to further another embodiment the programmable component is configured to receive and/or transmit a remote command, said remote command to determine the functional destiny of one or more of the TECUs and/or the function of a keys in a certain TECU.

According to further another embodiment the TECU comprises a circuitry housing encapsulating the circuitry to provide electrical isolation of the circuitry, and said housing comprising an attachment element for attaching to an adaptive frame and/or to a covering panel.

According to a second aspect of the present invention there is provided a method for installing a touch sensitive element the method comprising
installing in a wall a touch element circuitry unit (TECU) comprising a circuit housing encapsulating the TECU circuitry; and
placing over the TECU a covering panel, said panel comprising indications of where to place a finger to activate one or more of the TECUs.

An embodiment may involve installing attaching an adaptive frame to the TECU housing prior to installing in the wall.

An embodiment may involve installing a plurality of TECUs and placing over the plurality of TECUs a single covering panel.

According to a third aspect of the present invention there is provided a touch sensitive unit comprising circuitry and a circuitry housing encapsulating the circuitry, said housing providing electrical isolation of the circuitry.

According to an embodiment the housing comprises an attachment element for attaching to an adaptive frame and/or to a covering panel.

According to a fourth aspect of the present invention there is provided a programmable touch sensitive unit the unit comprising:
touch sensitive circuitry and
a wireless receiver and/or transmitter programmable component.

### BRIEF DESCRIPTION OF THE FIGURES

The invention will now be described in relation to certain examples and embodiments with reference to the following illustrative figures so that it may be more fully understood. In the drawings:

FIGS. 1A, 1B and 1C schematically illustrate touch element circuitry units (TECU), according to one embodiment of the invention;

FIG. 2 schematically illustrates a modular touch element system, according to an embodiment of the invention;

FIG. 3 schematically illustrates a modular touch element system, according to another embodiment of the invention;

FIG. 4 schematically illustrates a covering panel, according to embodiments of the invention;

FIG. 5 schematically illustrates a modular touch element system and covering panel, according to embodiments of the invention;

FIG. 6 schematically illustrates a remotely controlled system, according to embodiments of the invention;

FIG. 7A schematically illustrates a system including a unit according to embodiments of the invention; and

FIG. 7B schematically illustrates a panel of the system of FIG. 7A.

### DETAILED DESCRIPTION OF THE INVENTION

Embodiments of the present invention provide a touch sensitive module which is electrically insulated (and may thus be safely sold and handled as a separate, stand-alone unit) and which can be easily fit into any adaptive frame, providing a completely modular solution to consumers wishing to install, upgrade or just change the switches in their wall.

As opposed to existing touch sensitive switches, which require installing a pre-fabricated unit (which includes circuitry and a fixed covering panel) into an existing niche and adapting the niche to fit the pre-fabricated unit, a touch sensitive element according to embodiments of the invention may be set up in a consumer's home (or other surrounding) by installing a touch element circuitry unit (TECU) (which does not include a covering panel) in any niche in a wall and placing over the TECU a covering panel. In cases where the dimensions of the niche in the wall do not correlate to the TECU, an adaptive frame may be attached to the TECU to enable exact fitting into the niche in the wall.

The covering panel may include indications of where to place a finger to activate one or more of the TECUs.

In one embodiment more than one TECU may be installed (each TECU possibly being attached to a single adaptive frame or several TECUs being attached to a single adaptive frame) and a single covering panel may be placed over the plurality of units providing a single flat, smooth panel with which a user may interface, instead of having to install a plurality of panels, one for each TECU.

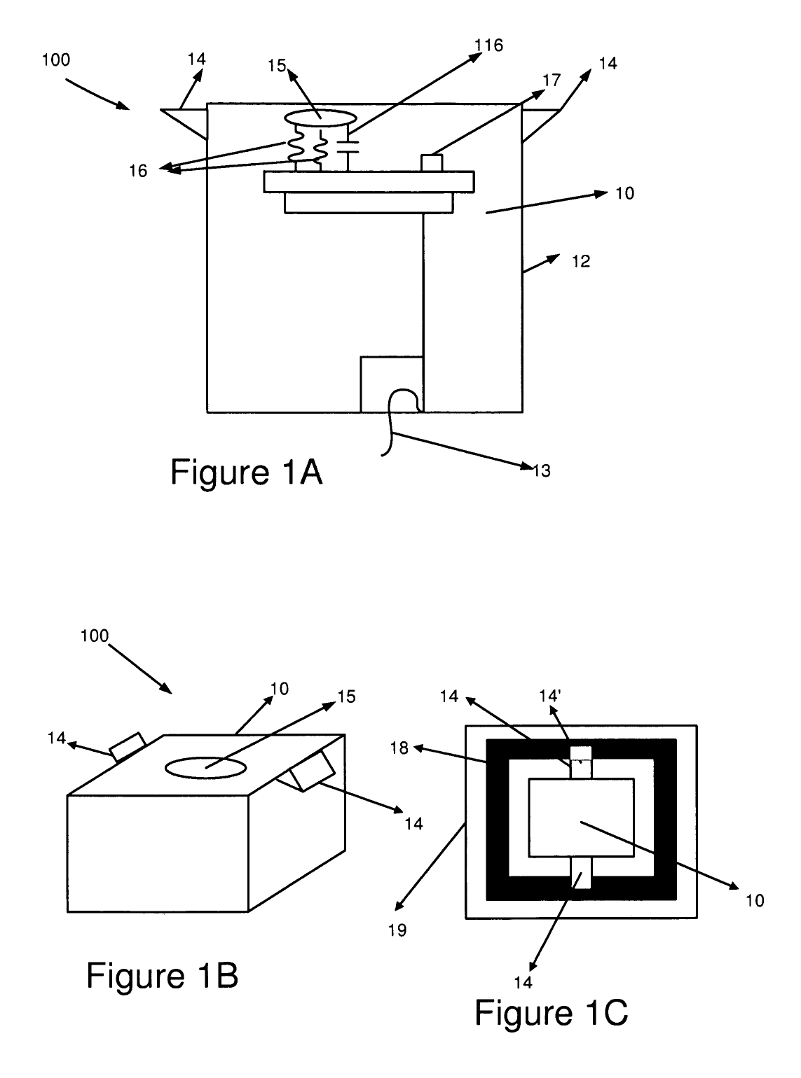

Reference is now made to FIG. 1A which is a cross section view of a TECU, and to FIGS. 1B and 1C which are schematic side and top views of TECUs according to embodiments of the invention.

The TECU 100 includes circuitry 10 and a circuitry housing 12. The housing 12 is typically made of insulating material such as plastic, rubber, glass or other silica or polymers. The housing 12 encapsulates the circuitry 10 such that the circuitry 10 is completely protected and entire TECU 100 is electrically insulated and may thus be safely handled. Wires 13 may be passed through an opening in the housing 12 to enable connecting the TECU 100 to an electrical network.

According to one embodiment the housing 12 includes one or more attachment element(s) 14 to enable attaching the TECU 100 to an adaptive frame 18. The attachment element 14 may be a snap type element configured to be pressureably snapped into place in a corresponding niche or element 14′ in an adaptive element 18. Other appropriate attachment elements may be used, such as sticky or magnetic elements. For example, element 14 may include a ferromagnetic material whereas element 14′ may include a magnet.

Alternatively, the attachment element 14 may be configured to attach directly onto a covering panel or onto electrical boxes or other items.

TECUs according to embodiments of the invention may be activated by touch, e.g., by capacity sensing, resistive touch panel, pressure such as a mechanically or a ‘pseudo mechanically’ activated push button, temperature change, humidity change, or any other activation technique or combination of techniques.

The circuitry 10 includes or is connected to a touch sensitive area 15, typically a capacitive sensitive area. The touch sensitive area 15 may be connected to or coupled with the circuitry 10 by elastomeric contacting elements 16 such as a zebra connector, conducting gasket or other appropriate, typically flexible, electrically contacting elements, or by connectors such as header and female connectors etc.

According to some embodiments, the touch sensitive module may be activated similar to a ‘mechanical switch’. For example, a covering panel 20 may include one or more movable parts which function as ‘keys’. The keys may include a ‘conductive element’. When the ‘conductive element’ of the keys is in proximity or in contact with the touch sensitive area 15, the touch sensitive area 15 will sense the ‘conductive element’ and the TECU will be activated and further execute a type of ‘push button’ operation e.g. ‘pseudo push button’ operation. Therefore, by pressing the covering panel at the indications of where to place a finger, a user will feel a mechanical press, for example by his finger pressure, indicating the activation or deactivation of the TECU.

The TECU 100 may also include a capacitor and/or a resistor 116 positioned in between the circuitry 10 of the TECU and the touch sensitive area 15. These elements—may function as a safety element by limiting the maximum possible leakage current in case of malfunction and to prevent electrocution.

The circuitry 10 may also include a wireless transceiver 17 for accepting and/or transmitting wireless signals. The transceiver 17 may be used to program and determine the functional and other destiny of the unit. Remote command/programming of the TECU according to embodiments of the invention will be further discussed below.

FIG. 1C schematically illustrates how an adaptive frame 18 may enable installing a TECU 10 into a niche 19 in the wall. Different sized and shaped adaptive frames 18 may be used to accommodate to different size and shape niches 19.

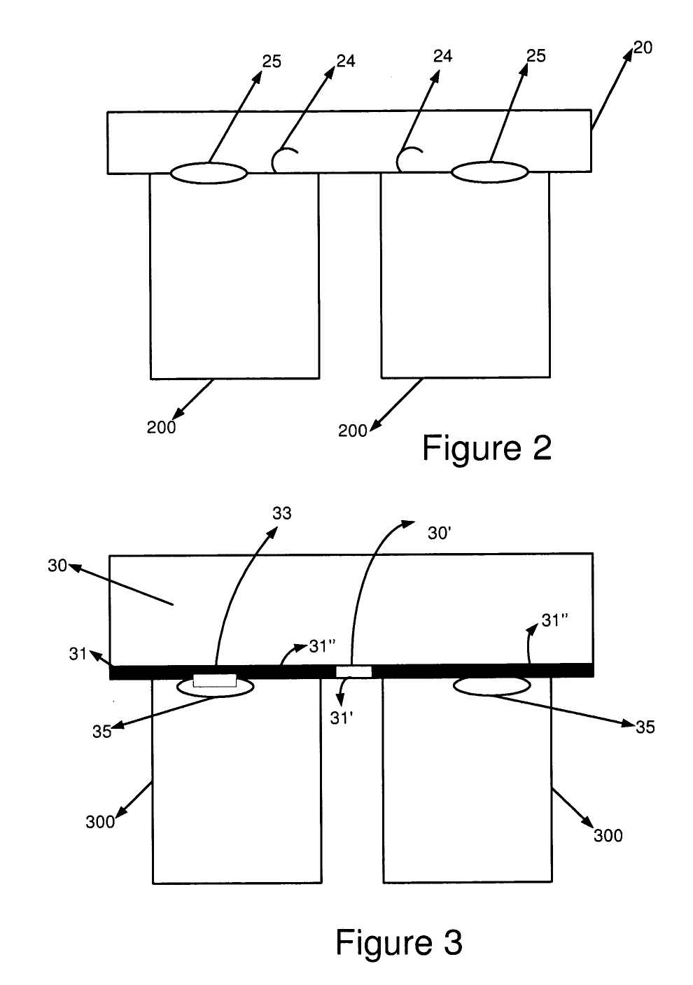

FIG. 2 schematically illustrates a modular touch element system according to an embodiment of the invention.

According to one embodiment a system includes a plurality of touch element circuitry units (TECUs) 200 and a single covering panel 20 to cover the plurality of TECUs 200. The covering panel 20 is configured to enable activation of one or more of the TECUs 200.

The covering panel 20 may be made of glass, plastic, ceramics or other suitable materials and may be designed according to the consumer's wishes. According to some embodiments the TECUs 200 may be have an attachment element 24 for securing the covering panel 20. According to other embodiments the covering panel 20 may be secured onto an adaptive frame (not shown here) or onto a wall.

TECUs used in this system may include circuitry and connecting elements as described herein and may be activated by touch, such as by capacitive sensing, resistive touch panel, pressure for example a mechanically activated unit e.g. ‘pseudo push button’ (as described above) or mechanical switch , temperature change, humidity change, or any other activation technique or combination of techniques.

According to one embodiment, schematically illustrated in FIG. 3, the system includes a conducting element 31 positioned in between the touch sensitive area, such as capacitive sensitive area 35 of the TECU 300 and the covering panel 30. The conductive element 31 is typically larger than the capacitive sensitive area 35, thereby effectively expanding the touch sensitive area of the system.

The conductive element 31 may be a conductive sheet integrated within the covering panel 30 or attached on to or printed on a surface of the covering panel 30. According to one embodiment the conductive element 31 is attached on or printed onto the surface of the covering panel 30′ which faces the circuitry of TECU 300.

According to one embodiment the conductive element 31 includes conducting areas 31″ and an insulating area 31′ such that a single, continuous covering panel 30 may be easily used to activate two or more TECUs 300. In other cases each of the TECUs or certain TECUs may have a dedicated covering panels instead a single covering panel for all TECUs.

A TECU 300 may include a coupling layer 33 positioned between the capacitive sensitive area 35 and the covering panel 30 to ensure better conductivity. The coupling layer may be made of, for example, conductive or dielectric material.

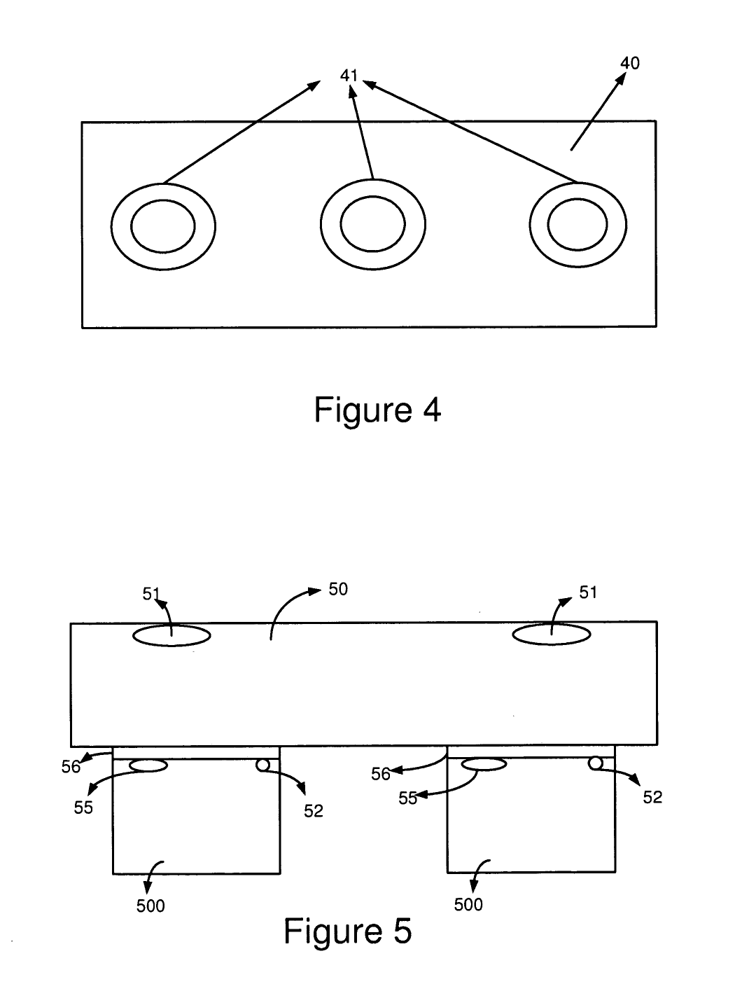

The covering panel 40, schematically illustrated in FIG. 4, may include indications 41 of where to place a finger to activate one or more of the touch element circuitry units or to press a mechanical switch. According to embodiments of the invention, a single covering panel 40 may cover several TECUs. The panel 40 may thus include several indications 41. According to another embodiment each of the TECUs or a specific TECUs may have a dedicated covering panel.

The indications 41 are typically aligned with a capacitive sensitive area of the underlying touch sensitive areas.

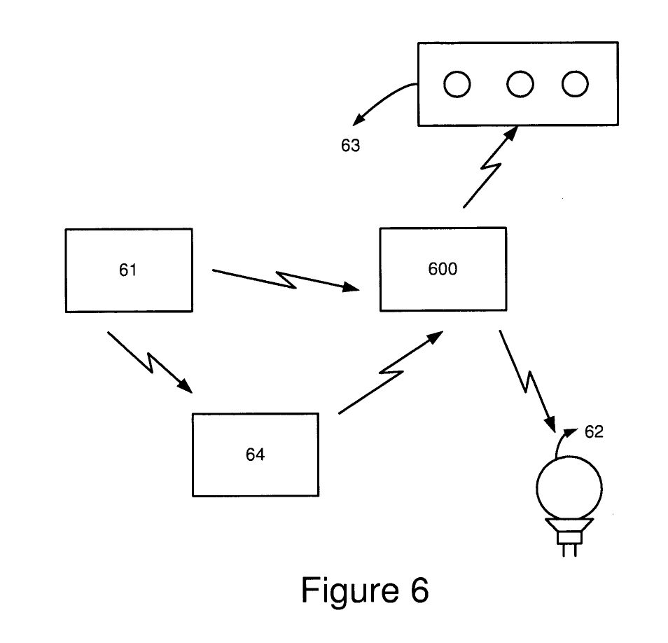

FIG. 5 schematically illustrates a system including several TECUs 500 and a single covering panel 50, according to an embodiment of the invention.

According to one embodiment the system may include a light source 52. According to one embodiment the covering panel 50 may include transparent sections to allow illumination from light source 52 to show through the covering panel 50. For example, indications 51 may be transparent or include a transparent section such that upon activation, or at any other desired time, the indications 51 may appear lit up. In addition to being esthetic, this feature may allow clear indication of the panel 50 in a dark room, for the convenience and safety of the user.

According to one embodiment a capacitive sensitive area 55 of the TECU 500 includes a conductive sheet 56, possibly having light reflecting properties. The conductive sheet 56 is typically positioned on top of the TECU 500 and under the covering panel 50. The conductive sheet 56 may include opaque and transparent sections, the transparent sections to allow illumination to show through. The light reflecting properties of the conductive sheet 56 may assist in collecting and directing illumination from the light source 52 to the transparent areas.

According to one embodiment The TECU 500 may have several contacts to the conductive sheet 56—so the conductive layer may designed as 1 2 3 or 4 different capacitive sensitive areas, which may use as several keys, each key can turn on or off a load or just sending a logical command to main system and the system my act according to a predefined programming. So the same TECU may use for several products just by changing the conductive layer.

According to one embodiment, schematically illustrated in FIG. 6, the system includes a programmable touch sensitive unit which includes touch sensitive circuitry and a programmable component. The programmable component may determine the type of activity and functional destiny of the unit.

According to one embodiment a TECU 600 may include a transceiver element which may accept and/or transmit a signal wirelessly (e.g., through WiFi, Bluetooth, ZigBee, or other protocol or Proprietary RF communication) or through a wired or other suitable connection from a remote control 61. The signal may be sent directly from the remote control 61 or through a central control unit 64.

Each transceiver element may be identified through unique URI (uniform resource identifier), URN (uniform resource name) and/or other electronic addresses.

According to some embodiments one or more TECUs 600 can be controlled using a single central unit 64.

The TECUs, in turn, control appliances, for example, light fixture 62 and/or other appliances or devices 63, such as, air conditioners, ovens, heaters, electrical curtains, video and audio systems and more.

A user may program a TECU 600, for example by using Internet communications protocols (e.g., Transmission Control Protocol (TCP) and Internet Protocol (IP)), to program a central unit 64, for example, to determine which fixtures and appliances will be activated by which TECUs and/or to determine a schedule of activation. The central unit 64 may then send a signal (possibly after receiving a signal from the remote control 61) to specific TECU (e.g., by using the unique URL of each transceiver element) to be activated and/or specify the mode of activity and/or to specify which functions the TECU will activate and/or their schedule.

The remote control 61 may interact directly with a TECU 600, or with a central unit 64. The remote control 61 may be a cell phone or other mobile device having a panel through which a user may program or choose options in a preprogrammed system.

According to some embodiments the central unit serves as a bridge in a possibly multi-component system in which a single controller may communicate with a plurality of TECUs. In its role as a bridge, the central unit may be a two part unit; a first part to user input typically over Internet communication protocols or 3G/4G telecommunication, and a second part configured to communicate with multiple transceivers (multiple transceivers in a single TECU or one transceiver per one TECU), typically wireless technology such as Bluetooth or ZigBee, or any wireless technology known in the art.

In a working example, a TECU 600 may receive a first signal from a remote control 61 to turn on light fixture 62 in a certain mode or schedule (e.g., light fixture 62 may be a light in the house kitchen). TECU 600 may turn on the kitchen light every day at 7 am and turn it off at 8 am, except for Saturday on which the light is turned on at 8 am and shut off at 9 am). TECU 600 may receive a second signal from the remote control 61 to change the schedule or turn on device 63 (e.g. device 63 may be the kitchen air conditioner and it may be activated in a schedule similar to the schedule of the kitchen light).

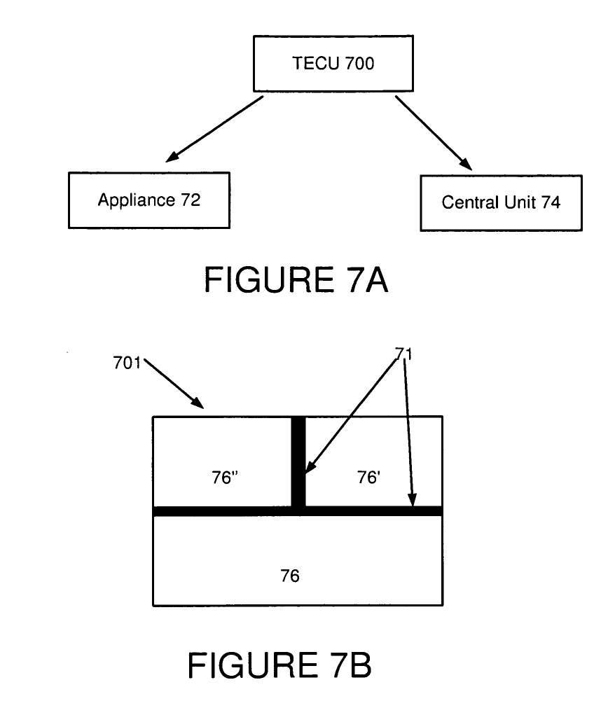

A system, according to embodiments of the invention, which includes a central unit and a TECU, is schematically illustrated in FIGS. 7A and 7B.

According to one embodiment the TECU 700 includes a microprocessor as well as a transceiver. The microprocessor can be used during communication with a central unit 74. According to one embodiment the microprocessor can be in communication with transceiver for communicating with the central unit 74 and/or the microprocessor can be connected to a circuit for directly controlling an appliance 72, such as a light bulb or other fixture.

A TECU 700 may have several capacitive areas, each capacitive area being connected to a different circuit, each circuit providing a different functionality.

For example, a sheet or layer 701 (FIG. 7B) includes several capacitive areas 76, 76′ and 76″ having insulating areas 71 in between. The layer 701 is made of conducting material and may be laid on (stuck on or otherwise attached on) a top panel of the TECU 700. Capacitive area 76 may be connected to a circuit for controlling an appliance 72 such that touching the area corresponding to capacitive area 76 causes the activation or deactivation of the appliance 72. Capacitive area 76′ may be connected to the microprocessor in the TECU 700 such that touching the area corresponding to capacitive area 76′ may initiate connection with the central unit 74 to provide a pre-programmed function (such as shutting off all the lights in the house). Capacitive area 76″ may be connected to the microprocessor in the TECU 700 such that touching the area corresponding to capacitive area 76″ may initiate connection with the central unit 74 to provide a different pre-programmed function (such as activating the air conditioner at a specific hour during the day). Thus, units according to embodiments of the invention may include “keys”, each key being able to turn on or off a load or being able to send a logical command to a central unit and the central unit may act according to a predefined programming. This way, a single TECU may be used for single or several functionalities and a single TECU may be “re-programmed” even after it has been installed, by simply using different layers (such as conductive stickers) on the TECU. Adding or changing a layer 701 on a TECU can affect the functionality of the TECU. For example, if the layer 701 has a single capacitive area, the TECU will have a single function. Using a layer 701 having two, three, four (or more) conductive areas renders the TECU multifunctional. A user may touch one conductive area to achieve a first function and a second conductive area to achieve a second function, and so on.

Thus, a system according to embodiments of the invention may be easily installed in pre-existing electrical networks and may be used to control multiple devices, each device possibly following its own schedule. For example, in a house, which may be a private residence, a hotel, a building of offices etc., and which includes 3 floors, each floor may have one or more TECUs installed and all the devices and fixtures on all floors may be wirelessly controlled through the installed TECUs.

In some embodiments a TECU as described above may be installed as a switch directly on devices or appliances (e.g., a TECU according to embodiments of the invention may be installed in or may replace an existing switch of a table lamp, air-conditioner, audio system and more such appliances.

1. A modular touch element system comprising
a plurality of touch element circuitry units (TECUs); and
at least one covering panel to cover the plurality of TECUs, said panel configured to enable activation of one or more of the TECUs.

2. The system of claim 1 wherein each TECU is configured to be activated by touch, by pressure, by temperature change, humidity change or a combination thereof.

3. The system of claim 1 wherein the TECU comprises a capacitive sensitive area.

4. The system of claim 3 wherein a TECU comprises an elastomeric contacting element to connect between the capacitive sensitive area and the circuitry of a TECU.

5. The system of claim 3 comprising a conducting element positioned in between the capacitive sensitive area of the TECU and the covering panel, said conductive element being larger than the capacitive sensitive area.

6. The system of claim 5 wherein the conducting element is integrated within the covering panel.

7. The system of claim 5 wherein the conductive element is a conductive sheet attached on to or printed on a surface of the covering panel, said surface facing the circuitry of the TECU.

8. The system of claim 3 wherein the TECU comprises a coupling layer, the coupling layer positioned between the capacitive sensitive area and the covering panel.

9. The system of claim 8 wherein the coupling layer is. elastic.

10. The system of claim 8 wherein the coupling layer is made of conductive or dielectric material.

11. The system of claim 3 comprising a capacitor and/or a resistor and/or dielectric material positioned in between the circuitry of the TECU and the capacitive sensitive area.

12. The system of claim 1 comprising a programmable component.

13. The system of claim 12 wherein the programmable component determines the functional destiny of the TECU.

14. The system of claim 12 wherein the programmable component is configured to receive and/or transmit a remote command, said remote command to determine the functional destiny of one or more of the TECUs and/or the function of a keys in a certain TECU.

15. The system of claim 1 wherein the covering panel comprises indications of where to place a finger to activate one or more of the touch element circuitry units.

16. The system of claim 15 wherein the indications are aligned with a capacitive sensitive area.

17. The system of claim 1 comprising an illumination source.

18. The system of claim 17 wherein the covering panel comprises a transparent section to allow illumination to show through.

19. The system of claim 17 wherein the capacitive sensitive area comprises a conductive sheet having light reflecting properties, the conductive sheet positioned between the capacitive sensitive area and the covering panel.

20. The system of claim 19 wherein the conductive sheet comprises opaque and transparent sections, the transparent sections to allow illumination to show through.

21. The system of claim 1 wherein the TECU comprises a circuitry housing encapsulating the circuitry to provide electrical isolation of the circuitry, and said housing comprising an attachment element for attaching to an adaptive frame and/or to a covering panel.

22. The system of claim 21 wherein the covering panel is configured to fit over the adaptive frame.

23. The system of claim 21 wherein the adaptive frame comprises movable parts.

24. The system of claim 23 wherein the movable parts comprises a conductive element configured to activate the TECU when the conductive element is in proximity with the touch sensitive area.

25. The system of claim 23 wherein the mechanical switch is a push button located in the vicinity to the touch sensitive area.

26. A method for installing a touch sensitive element the method comprising installing in a wall a touch element circuitry unit (TECU) comprising a circuit housing encapsulating the TECU circuitry; and
placing over the TECU a covering panel, said panel comprising indications of where to place a finger to activate one or more of the TECUs.

27. The method of claim 26 comprising installing attaching an adaptive frame to the TECU housing prior to installing in the wall.

28. The method of claim 26 comprising installing a plurality of TECUs and placing over the plurality of TECUs a single covering panel.

29. A touch sensitive unit comprising circuitry and a circuitry housing encapsulating the circuitry, said housing providing electrical isolation of the circuitry.

30. The unit of claim 29 wherein the housing comprises an attachment element for attaching to an adaptive frame and/or to a covering panel.

31. The unit of claim 29 comprising a capacitive sensitive area.

32. The unit of claim 31 comprising an elastomeric contacting element to connect between the capacitive sensitive area and the circuitry.

33. The unit of claim 29 comprising a wireless receiving and/or transmitting component.

34. The unit of claim 33 wherein the wireless receiving and/or transmitting component is to determine the functional destiny of one or more units.

35. The unit of claim 31 comprising a conductive layer changeably laid upon a top surface of the unit, the layer comprising the capacitive sensitive area.

36. The unit of claim 35 comprising a plurality of capacitive sense inputs, each input to control a different functionality, and wherein the conductive layer comprises a plurality of capacitive sensitive areas, each capacitive sensitive area connected to a different input.

37. A programmable touch sensitive unit the unit comprising
touch sensitive circuitry and
a wireless receiver and/or transmitter programmable component.

38. The unit of claim 37 wherein the programmable component is to determine the functional destiny of the unit.
